(19) United States
(12) Patent Application Publication
(10) Pub. No.: US 2026/0282897 A1
(43) Pub. Date: Sep. 17, 2026

(54) SEMICONDUCTOR PACKAGE AND METHODS FOR FORMING THE SAME

(71) Applicant: Taiwan Semiconductor Manufacturing Company Limited, Hsinchu (TW)

(72) Inventors: Sheng-Ta LIN, Gongguan Township (TW); Hsuan-Cheng KUO, Hsinchu (TW); Han Hsiang LIAO, Hsinchu (TW)

(21) Appl. No.: 19/079,619

(22) Filed: Mar. 14, 2025

(51) Int. Cl. H01L 23/367; H01L 21/50; H01L 23/00; H01L 23/373; H01L 23/538; H01L 25/07

(52) U.S. Cl. CPC H10W 40/22; H10W 40/255; H10W 95/00; H10W 70/611; H10W 72/341; H10W 72/353; H10W 90/00; H10W 90/401; H10W 90/734

(57) ABSTRACT

A semiconductor package including a lid having a “pre-buckled” configuration. The lid includes a sidewall portion attached to a package substrate and laterally surrounding a package structure including semiconductor die(s), a central portion in thermal contact with the package structure, and a plurality of connecting arms extending between the sidewall portion and the central portion of the lid. The central portion is vertically recessed relative to the sidewall portion and the connecting arms extend in an oblique vertically downward direction between the sidewall portion and the central portion of the lid. Accordingly, during high-temperature conditions, thermal expansion of the connecting arms occurs along a vertically downward direction to displace the central portion towards the package structure. Effective thermal contact between the lid and the package structure may thereby be maintained during high-temperature conditions.

### BACKGROUND

Semiconductor devices are used in a variety of electronic applications, such as personal computers, cell phones, digital cameras, and other electronic equipment, as examples. Semiconductor devices are typically fabricated by sequentially depositing insulating or dielectric layers, conductive layers, and semiconductive layers over a semiconductor substrate, and patterning the various material layers using lithography and etch to form circuit components and elements thereon. Dozens or hundreds of integrated circuits are typically manufactured on a single semiconductor wafer, and individual dies on the wafer are singulated by sawing between the integrated circuits along a scribe line. The individual dies are typically packaged separately, in multi-chip modules, or in other types of packaging, for example.

In semiconductor packages, particularly semiconductor packages with relatively higher power utilization, excessive heat generation within the package and poor heat dissipation characteristics can have a number of undesirable effects, including hindered package performance and/or damage to components within the package. There is a continuing need for improvements of semiconductor packages.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a top view of a package structure according to various embodiments of the present disclosure.

FIG. 1B is a vertical cross-sectional view of the package structure taken along line A-A′ in FIG. 1A.

FIG. 2A is a top view of a semiconductor package including the package structure mounted to a package substrate according to various embodiments of the present disclosure.

FIG. 2B is a vertical cross-sectional view of the semiconductor package 100 taken along line A-A′ in FIG. 2A.

FIG. 3A is a top view of the semiconductor package including a thermal interface material (TIM) layer over the upper surface of the package structure according to various embodiments of the present disclosure.

FIG. 3B is a vertical cross-sectional view of the semiconductor package taken along line A-A′ in FIG. 3A.

FIG. 4A is a top view of the semiconductor package including a lid located on the package substrate according to various embodiments of the present disclosure.

FIG. 4B is a vertical cross-sectional view of the semiconductor package taken along line B-B′ in FIG. 4A.

FIG. 5 is a top view of the semiconductor package including a lid located on the package substrate according to another embodiment of the present disclosure.

FIG. 6A is a top view of the semiconductor package including a lid located on the package substrate according to another embodiment of the present disclosure.

FIG. 6B is a vertical cross-sectional view of the semiconductor package taken along line A-A′ in FIG. 6A.

FIG. 7 is a flow diagram illustrating a method for fabricating a semiconductor package according to various embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

Typically, in a semiconductor package, a number of semiconductor integrated circuit (IC) dies (i.e., “chips”) may be mounted onto a common substrate. The semiconductor package often includes a lid composed of a thermally-conductive material (e.g., a metal or metal alloy, such as copper) that encloses the semiconductor dies to protect them from damage. The lid may also provide sufficient heat dissipation from the package. The lid may be located over and in thermal contact with the semiconductor dies. Heat energy from the semiconductor dies may be transferred from the upper surfaces of the semiconductor dies into the lid and ultimately dissipated to the surrounding environment. In some embodiments, a thermal interface material (TIM), such as graphite or a metal material, may be provided between the semiconductor dies and the lid to promote heat transfer between the semiconductor dies and the lid.

An issue with semiconductor packages utilizing a thermally-conductive lid may be that advanced packaging designs for high-performance applications are often characterized by high-power operation and tend to generate higher temperatures. During high temperature conditions, the lid and the underlying substrate on which the semiconductor dies are mounted may expand and/or deform due to thermal effects. This may result in the displacement of the lid and the substrate along opposite directions. For example, under high temperatures, the central region of the substrate on which the semiconductor dies are attached may tend to move in a downward direction away from the lid, while the lid may expand in an upward direction away from the substrate and the semiconductor dies. The presence of a TIM may not be sufficient to maintain thermal contact between the lid and the semiconductor dies, since in the case of a graphite-based TIM, the TIM is typically attached to the semiconductor dies but has no adhesion to the lid. In the case of a metal-based TIM, the high temperature conditions may partially melt the TIM causing the metal-based TIM to lose constraint to the lid. Consequently, the lid and semiconductor dies may be separated and thereby lose the heat conduction path from the semiconductor dies through the lid. The heat dissipation performance of the semiconductor package may thus be reduced, which may result in poor performance and/or damage to the semiconductor package.

In order to improve the thermal management in semiconductor packages, various embodiments of the present disclosure include a semiconductor package including a lid having a “pre-buckled” configuration. The lid may be disposed on a package substrate having a package structure including one or more semiconductor dies mounted thereto. The lid may include a sidewall portion attached to the package substrate and laterally surrounding the package structure, a central portion in thermal contact with an upper surface of the package structure, and a plurality of connecting arms extending between the sidewall portion and the central portion of the lid. The lid may have a pre-buckled configuration in which the central portion of the lid may be recessed from the upper portion of the sidewall portion to which the connecting arms may be attached. Thus, the connecting arms may extend in an oblique vertically downward direction between the sidewall portion and the central portion of the lid. Accordingly, during high-temperature conditions, thermal expansion of the connecting arms occurs along a vertically downward direction such that the central portion of the lid is displaced downwards towards the underlying package structure. Effective thermal contact between the lid and the package structure may thereby be maintained under high-temperature conditions.

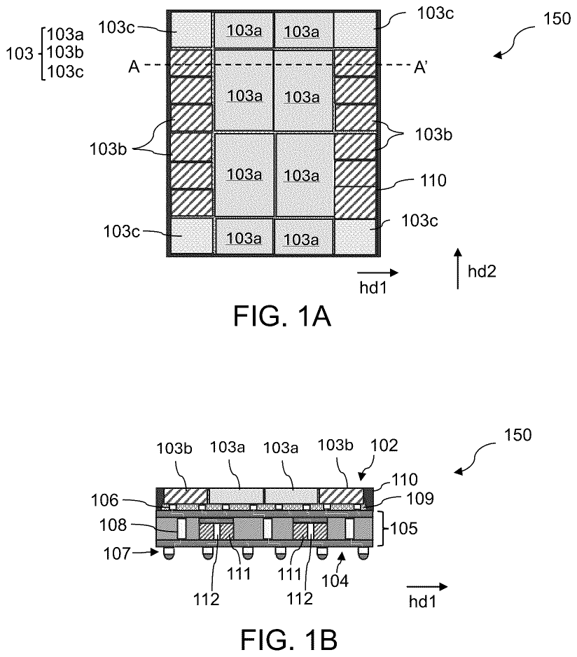

FIG. 1A is a top view of a package structure 150 according to various embodiments of the present disclosure. FIG. 1B is a vertical cross-sectional view of the package structure 150 taken along line A-A′ in FIG. 1A. Referring to FIGS. 1A and 1B, the package structure 150 may include a plurality of semiconductor dies 103. The package structure 150 may include, for example, at least one first semiconductor die 103a and at least one second semiconductor die 103b. The first semiconductor die(s) 103a may include at least one logic die, such as a system-on-a-chip (SOC) die, a CPU die, an application specific integrated circuit (ASIC) die, a GPU die, etc. The second semiconductor die(s) 103b may include at least one memory die, such as a high bandwidth memory (HBM) die which may include a vertical stack of interconnected memory dies, and/or a dynamic random access memory (DRAM) die. FIGS. 1A and 1B illustrate an embodiment including a plurality of first semiconductor dies 103a (i.e., logic dies) laterally surrounded by a plurality of second semiconductor dies 103b (i.e., memory dies). In some embodiments, the package structure 150 may additionally include at least one non-functional or “dummy” semiconductor die 103c that may provide in-line process structure uniformity and/or routing of electrical signals. Other configurations of the semiconductor dies 103 are within the contemplated scope of disclosure.

Referring to FIG. 1B, the plurality of semiconductor dies 103 may be mounted to an interposer 105 that may support the semiconductor dies 103. The interposer 105 may provide electrical interconnections to and/or between the various semiconductor dies 103. In the embodiment illustrated in FIG. 1B, the interposer 105 may be an organic interposer including a polymer dielectric material (e.g., a polyimide material). Other types of interposers 105 are within the contemplated scope of disclosure. Conductive features (e.g., metal lines and vias) may extend through the interposer 105 between the upper bonding surfaces and lower bonding surfaces of the interposer 105. In some embodiments, the conductive features may include through-insulator vias 108 (TIVs). In the embodiment illustrated in FIG. 1B, the interposer 105 may also include at least one local silicon interconnect (LSI) structure 111 embedded within the polymer dielectric material of the interposer 105. The LSI structure(s) 111 may provide electrical interconnections between the various semiconductor dies 103 of the package structure 150. In some embodiments, the LSI structure(s) 111 may include one or more through-silicon vias 112 (TSVs).

In other embodiments, the interposer 105 may be a semiconductor interposer, such as a silicon interposer, having a plurality of interconnect structures (e.g., TSVs) extending therethrough. In still further embodiments, the interposer 105 may be an organic interposer that may not include LSI structures 111 such that interconnections between the different semiconductor dies 103 may be made through the organic interposer. Other suitable configurations for the interposer 105 are within the contemplated scope of the disclosure.

The semiconductor dies 103 may be bonded to the upper surface of the interposer 105 by first bonding features 106. The first bonding features 106 may include microbump bonding structures. Other suitable bonding structures are within the contemplated scope of disclosure. A first underfill material portion 109 may be provided in the spaces surrounding the first bonding features 106 and between the bottom surfaces of the semiconductor dies 103 and the upper surface of the interposer 105. The first underfill material portion 109 may also be provided in the spaces laterally separating adjacent semiconductor dies 103 of the package structure 150. In various embodiments, the first underfill material portion 109 may be composed of an epoxy-based material, which may include a composite of resin and filler materials. Other underfill materials are within the contemplated scope of disclosure. A molding portion 110, which may be composed of an epoxy-based material, may be located around the periphery of the semiconductor dies 103 and the first underfill material portion 109. The upper surfaces of the semiconductor dies 103 and the molding portion 110 may form the upper surface 102 of the package structure 150. In some embodiments, the upper surface 102 of the package structure 150 may be a substantially flat co-planar surface.

The lower surface of the interposer 105 may form the lower surface 104 of the package structure 150. In various embodiments, second bonding features 107 may be located on the lower surface 104 of the interposer 105. In some embodiments, the second bonding features 107 may include metal pillars capped by a solder material. Other suitable structures and materials for the second bonding features 107 are within the contemplated scope of disclosure.

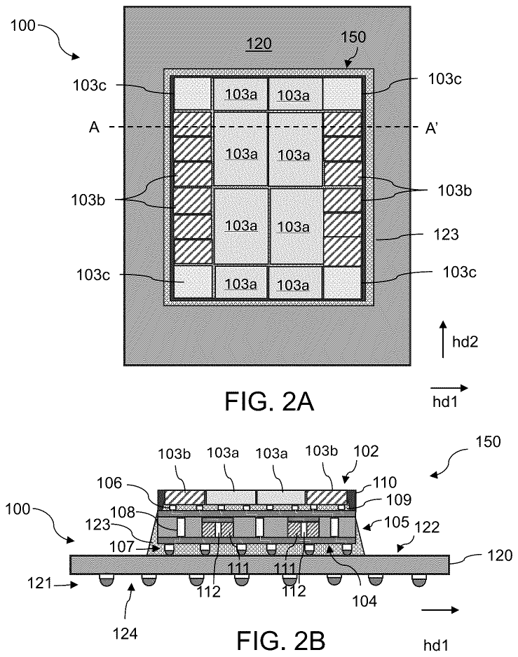

FIG. 2A is a top view of a semiconductor package 100 including the package structure 150 mounted to a package substrate 120 according to various embodiments of the present disclosure. FIG. 2B is a vertical cross-sectional view of the semiconductor package 100 taken along line A-A′ in FIG. 2A. Referring to FIGS. 2A and 2B, the package substrate 120 may have a first (i.e., upper) surface 122 and a second (i.e., bottom) surface 124. The package substrate 120 may include a suitable support element on which an interposer 105 and/or a plurality of semiconductor dies 103 may be mounted. In various embodiments, the package substrate 120 may include a suitable dielectric material. In some embodiments, the dielectric material of the package substrate 120 may include an organic dielectric material. In one non-limiting embodiment, the package substrate 120 may include a solid substrate core composed of a sheet of laminate reinforced resin with layers of a polymer-based dielectric material, such as Ajinomoto Buildup Film (ABF)® product, located over the surfaces of the substrate core. Conductive interconnect features, e.g., metal lines, vias and/or bonding pads (not expressly shown in FIGS. 2A and 2B) may be located within the dielectric material(s) of the package substrate 120 and may between the first side 122 and the second side 124 of the package substrate 120. An optional outer coating layer (e.g., a solder resist layer) may be located on the first side 122 and/or the second side 124 of the package substrate 120. Other suitable materials and/or configurations for the package substrate 120 are within the contemplated scope of disclosure.

In various embodiments, the bottom side of the interposer 105 may be mounted to the first (i.e., upper) side 122 of the package substrate 120 via the above-described second bonding features 107. In some embodiments, the first side 122 of the package substrate 120 may include a plurality of bonding pads that may have the same arrangement as the second bonding features 107 on the bottom side of the interposer 105. A solder reflow process may be used to mechanically and electronically bond the second bonding features 107 of the interposer 105 to the corresponding bonding pads on the package substrate 120. A second underfill material portion 123 may be provided between the underside of the interposer 105 and the first side 122 of the package substrate 120 and laterally surrounding the second bonding features 107. The second underfill material portion 123 may optionally extend over the side surfaces of the interposer 105. The second underfill material portion 123 may be similar or identical to the first underfill material portion 109 described above.

A plurality of third bonding features 121 may be located on the second (i.e., bottom) side 124 of the package substrate 120. The third bonding features 121 may enable the semiconductor package 100 to be mounted to a suitable support structure, such as a printed circuit board (PCB). In some embodiments, the third bonding features 121 may include a plurality of solder balls.

Although FIGS. 2A and 2B illustrate a semiconductor package 100 including a plurality of semiconductor dies 103 mounted to a package substrate 120 via an interposer 105, it will be understood that other configurations for the semiconductor package 100 are within the contemplated scope of disclosure. For example, a semiconductor package 100 according to various embodiments may include an integrated fan-out configuration in which multiple semiconductor dies 103 may be mounted to the package substrate 120 by a redistribution layer (RDL), a front-end three-dimensional (3D) package configuration in which a plurality of vertically-stacked, direct-bonded semiconductor dies 103 are mounted on the package substrate 120 by an RDL, or various combinations thereof.

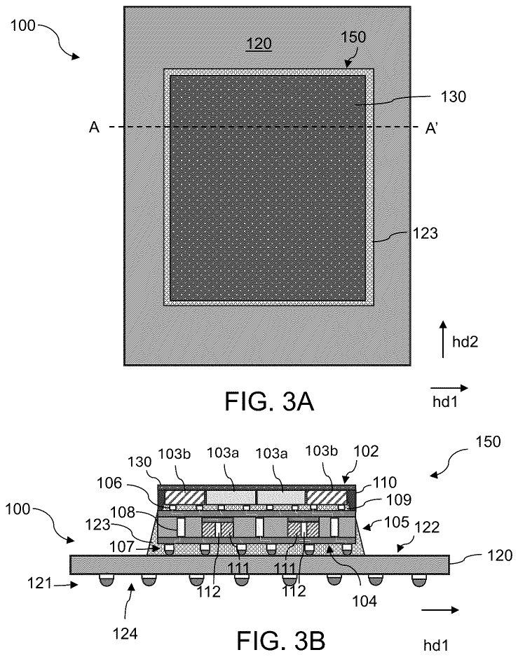

FIG. 3A is a top view of the semiconductor package 100 including a thermal interface material (TIM) layer 130 over the upper surface 102 of the package structure 150 according to various embodiments of the present disclosure. FIG. 3B is a vertical cross-sectional view of the semiconductor package 100 taken along line A-A′ in FIG. 3A. Referring to FIGS. 3A and 3B, a TIM layer 130 may be provided over the upper surface 102 of the package structure 150. In the embodiment of FIGS. 3A and 3B, the TIM layer 130 is located over the entire upper surface 102 of the package structure 150, including over the semiconductor dies 103 and the molding portion 110. In other embodiments, the TIM layer 130 may be located over a portion of the upper surface 102 of the package structure 150, such as over the first semiconductor dies 103a and the second semiconductor dies 103b but may not be present over the dummy semiconductor dies 103c and/or the molding portion 110. The TIM layer 130 may include a suitable thermally conductive material, such as a graphite-based or metallic material. In some non-limiting embodiments, the TIM layer 130 may be applied as a sheet over the upper surface 102 of the package structure 150. The sheet may be adhered to the upper surface 102 of the package structure using an adhesive or another suitable process. Other configurations for the TIM layer 130 are within the contemplated scope of disclosure. In some embodiments, the TIM layer 130 may include a multi-layer structure composed of thermally conductive material(s). The TIM layer 130 may have a substantially planar upper surface in various embodiments.

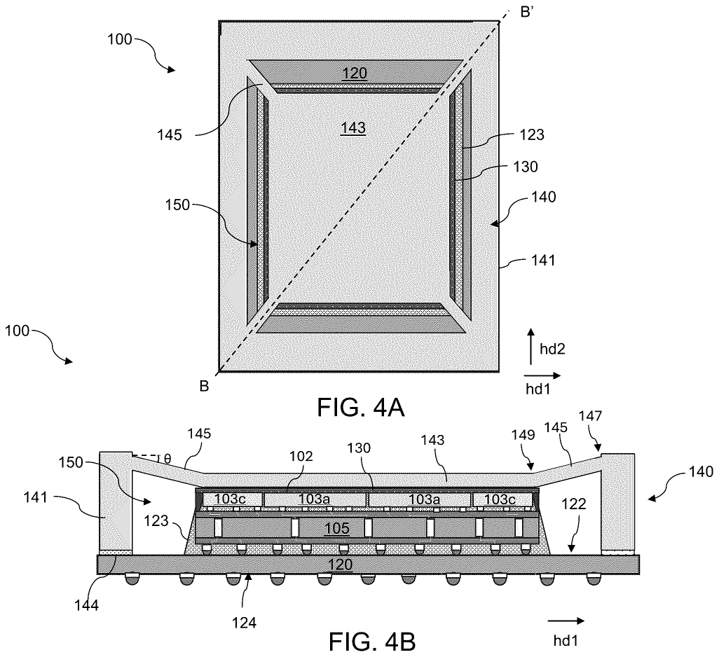

FIG. 4A is a top view of the semiconductor package 100 including a lid 140 located on the package substrate 120 according to various embodiments of the present disclosure. FIG. 4B is a vertical cross-sectional view of the semiconductor package 100 taken along line B-B′ in FIG. 4A. Referring to FIGS. 4A and 4B, a lid 140 may be disposed on the package substrate 120. The lid may include a sidewall portion 141 that laterally surrounds the package structure 150, a central portion 143 located over the package structure 150, and a plurality of connecting arms 145 extending between the sidewall portion 141 and the central portion 143. The sidewall portion 141 of the lid 140 may be attached to the upper surface 122 of the package substrate 120 via a suitable adhesive 144. In various embodiments, the adhesive 144 may be a thermally-conductive adhesive. Other suitable adhesive materials are within the contemplated scope of disclosure. The sidewall portion 141 in the embodiment of FIGS. 4A and 4B has a rectangular shape, although it will be understood that other shapes, such as a square shape, a circular shape, etc., may also be utilized.

The central portion 143 of the lid 140 may be a generally plate-like element having a substantially planar lower surface that contacts the TIM layer 130 located over the upper surface 102 of the package structure 150. In embodiments in which the package structure 150 lacks a TIM layer 130, the central portion 143 of the lid 140 may directly contact all or a portion of the upper surface 102 of the package structure 150 formed by the semiconductor dies 103 and the molding portion 110. In some embodiments, a thickness of the central portion 143 of the lid 140 may be between about 2-3 mm, although greater and lesser thicknesses may also be utilized. The central portion 143 of the lid 140 in the embodiment of FIGS. 4A and 4B has a rectangular shape, although it will be understood that other shapes, such as a square shape, a circular shape, etc., may also be utilized.

Each of the connecting arms 145 may be coupled to the sidewall portion 141 on a first end 147 of the connecting arm 145 and to the central portion 143 on a second end 149 of the connecting arm 145. The lid 140 may include open regions between the connecting arms 145. The embodiment illustrated in FIGS. 4A and 4B includes four connecting arms 145 each extending between respective corner regions of the sidewall portion 141 to the adjacent corner regions of the central portion 143. Other configurations for the connecting arms 145 may be utilized, such as described in further detail below.

In various embodiments, the connecting arms 145 may have a “pre-buckled” configuration such that the connecting arms 145 extend along an oblique direction (i.e., neither horizontal nor vertical) between the sidewall portion 141 and the central portion 143 of the lid 140. In various embodiments, the central portion 143 of the lid 140 may be vertically recessed relative to the upper portion of the sidewall portion 141 to which the connecting arms 145 are attached. Thus, the connecting arms 145 may extend in an oblique vertically downward direction between the sidewall portion 141 and the central portion 143. In some embodiments, a line segment extending between the first end 147 of the connecting arms 145 where the connecting arms 145 connect to the sidewall portion 141 and the second end 149 of the connecting arms 145 where the connecting arms 145 connect to the central portion 143 may have an angle θ that is between about −5° and about −25° with respect to a horizontal plane (i.e., a plane parallel to the first horizontal direction hd1 and the second horizontal direction hd2). However, it will be understood that greater and lesser angles for the line segment may be utilized.

In various embodiments, the pre-buckled configuration of the connecting arms 145 may function similarly to buckle-type electrothermal actuators that are utilized in microelectromechanical systems (MEMS). That is, the connecting arms 145 may be pre-buckled to constrain the motion of the connecting arms 145 due to thermal expansion along a desired direction. In some embodiments, the lid 140 may function similarly to a “V-beam” actuator in which a plurality of beams having a chevron shape are connected together at their midpoint to a moveable tip or shuttle. When the beams are heated (e.g., such as by applying a current to the beams), the resultant thermal expansion of the V-shaped beams causes the beams to collectively displace the tip along a desired direction.

In the lid 140 as shown in FIGS. 4A and 4B, pairs of connecting arms 145 on opposite sides of the central portion 143 may form a V-shape when viewed in vertical cross-section, with the central portion 143 of the lid 140 functioning as the connecting point for the connecting arms 145 and the vertex of the “V”. Heat generated by components of the semiconductor package 100 (e.g., the semiconductor dies 103) may cause the connecting arms 145 to thermally expand and collectively displace the central portion 143 of the lid 140 in a vertically downward direction, towards the TIM layer 130 and the upper surface 102 of the package structure 150. Accordingly, the thermal expansion of the lid 140 may be constrained such that the central portion 143 of the lid 140 moves downwards towards the underlying package structure 150 during high-temperature operation. Effective thermal contact between the lid 140 and the package structure 150 may therefore be maintained under high temperature conditions.

In the embodiment shown in FIGS. 4A and 4B, each of the connecting arms 145 is a straight arm extending between the sidewall portion 141 and the central portion 143 of the lid 140. However, other configurations for the connecting arms 145 are within the contemplated scope of disclosure. For example, the connecting arms 145 may extend in a curved shape between the sidewall portion 141 and the central portion 143 of the lid 140. Pairs of connecting arms 145 on opposite sides of the central portion 143 may form a U-shape when viewed in vertical cross-section, with the central portion 143 of the lid 140 functioning as the connecting point for the connecting arms 145 and the trough of the “U”. In still further embodiments, each of the connecting arms 145 may extend diagonally downward between the sidewall portion 141 and the central portion 145 as shown in FIGS. 4A and 4B, and may also include a bent region, such as a bent region resembling the letter “Z.” Thermal expansion of the connecting arms 145 may cause the bent regions of the connecting arms 145 to partially straighten out such that the central portion 143 is displaced vertically downwards towards the package structure 150.

In various embodiments, the lid 140 may include a thermally conductive material, such as a metal material (e.g., copper). In some embodiments, the lid 140 may be formed as a unitary component. In some embodiments, the lid 140 may be formed via a machining process, such as using a Computer Numerical Control (CNC) process.

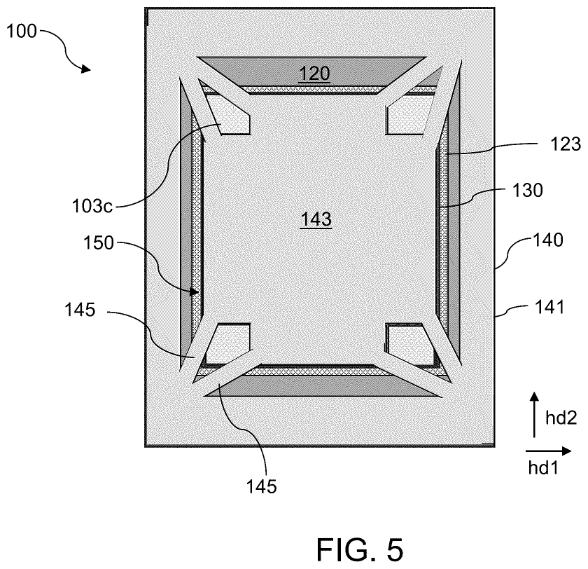

FIG. 5 is a top view of the semiconductor package 100 including a lid 140 located on the package substrate 120 according to another embodiment of the present disclosure. In the embodiment of FIG. 5, the central portion 143 of the lid 140 may include cutout regions over portions of the package structure 150. In some embodiments, the cutout regions may correspond to the locations of non-heat generating components of the package structure 150, such as the above-described dummy semiconductor dies 103c. In the embodiment of FIG. 5, the cutout regions are located in the corners of the central portion 143 of the lid 140, but it will be understood that one or more cutout regions could be in other locations of the central portion 143. Pairs of connecting arms 145 may extend from the corners of the sidewall portion 141 to either side of each of the cutout regions of the central portion 143. The lid 140 may otherwise be equivalent to the lid 140 described above with reference to FIGS. 4A and 4B. The cutout regions of the central portion 143 of the lid may reduce material costs, and the additional connecting arms 145 may help to increase the stiffness of the lid 140.

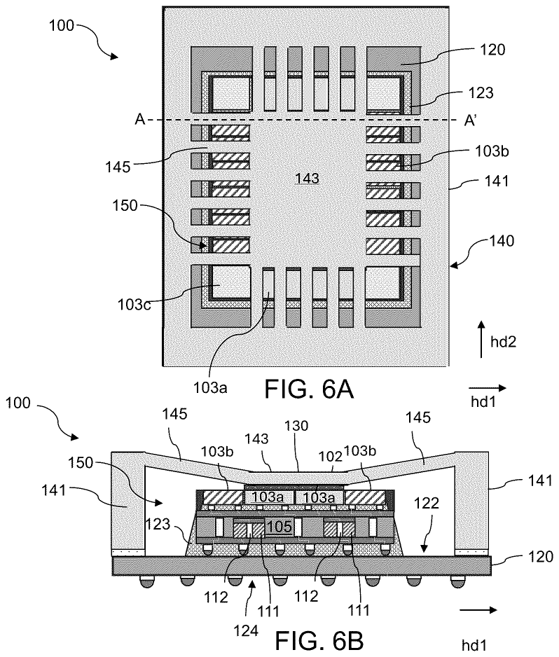

FIG. 6A is a top view of the semiconductor package 100 including a lid 140 located on the package substrate 120 according to another embodiment of the present disclosure. FIG. 6B is a vertical cross-sectional view of the semiconductor package 100 taken along line A-A′ in FIG. 6A. Referring to FIGS. 6A and 6B, the central portion 143 of the lid 140 may cover a portion of the package structure 150. In the embodiment of FIGS. 6A and 6B, the central portion 143 of the lid 140 is located over a central region of the package structure 150, but the central portion 143 is not located over peripheral regions of the package structure 150. For example, the central portion 143 of the lid 140 may cover first semiconductor dies 103a within the central region of the package structure 150, but may not cover the first semiconductor dies 103a, the second semiconductor dies 103b and the dummy semiconductor dies 103c around the periphery of the package structure 150. As shown in FIG. 6B, the TIM layer 130 may be located between the upper surface 102 of the package structure 150 and the central portion 143 of the lid 140 but may not be present over portions of the package structure 150 that are not covered by the central portion 143 of the lid 140. Alternatively, the TIM layer 130 may cover the entire upper surface 102 of the package structure 150. In some embodiments, the TIM layer 130 may be omitted entirely.

Referring again to FIGS. 6A and 6B, the connecting arms 145 may extend from the lateral side surfaces of the sidewall portion 141 lateral side surfaces of the central portion 143. A first group of connecting arms 145 may extend parallel to one another along the first horizontal direction hd1 and a second group of connecting arms 145 may extend parallel to one another along the second horizontal direction hd2. The connecting arms 145 on opposite sides of the central portion 143 may be aligned with one another. Thus, pairs of connecting arms 145 on opposite sides of the central portion 143 may form a “V” shape as shown in the vertical cross-section view of FIG. 6B. The additional connecting arms 145 in the embodiment of FIGS. 6A and 6B may increase the stiffness of the lid.

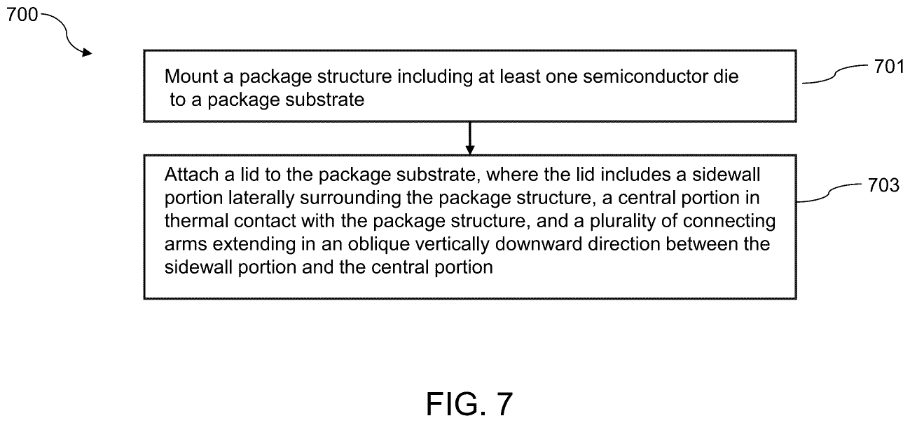

FIG. 7 is a flowchart illustrating a method 700 of fabricating a semiconductor package 100 according to one or more embodiments. Referring to FIGS. 1A-3B and 7, in step 701 of method 700, a package structure 150 including one or more semiconductor dies 103 may be mounted to a package substrate. Referring to FIGS. 4A-7, in step 703 of method 700, a lid may be attached to the package structure, where the lid includes a sidewall portion laterally surrounding the package structure, a central portion in thermal contact with an upper surface of the package structure, and a plurality of connecting arms extending in an oblique vertically downward direction between the sidewall portion and the central portion of the lid.

Referring to all drawings and according to various embodiments of the present disclosure, a semiconductor package 100 may include a package substrate 120, a package structure 150 including at least one semiconductor die 103 mounted to the package substrate 120, and a lid 140 including a sidewall portion 141 attached to the package substrate 120 and laterally surrounding the package structure 150, a central portion 143 in contact with an upper surface 102 of the package structure 150, and a plurality of connecting arms 145 extending between the sidewall portion 141 and the central portion 143 of the lid 140, where the central portion 143 of the lid 140 is vertically recessed from an upper portion of the sidewall portion 141 to which the plurality of connecting arms 145 are attached, and at least one of the plurality of connecting arms 145 extends in an oblique vertically downward direction between the sidewall portion 141 and the central portion 143 of the lid 140.

In an embodiment, a plurality of the connecting arms 145 extend in an oblique vertically downward direction between the sidewall portion 141 and the central portion 143 of the lid 140, and each of the plurality of connecting arms 145 extending in an oblique vertically downward direction includes a first end 147 connected to the sidewall portion 141 and a second end 149 connected to the central portion 143, and a line segment extending between the first end 147 and the second end 147 of each of the connecting arms 145 extending in an oblique vertically downward direction has an angle θ between −5° and −25° with respect to a horizontal plane.

In another embodiment, the package structure 150 includes a plurality of semiconductor dies 103 surrounded by a molding portion 110, where the upper surface 102 of the package structure 150 is formed by upper surfaces of the plurality of semiconductor dies 103 and the molding portion 110.

In another embodiment, the package structure 150 further includes an interposer 105 located between the plurality of semiconductor dies 103 and the package substrate 120.

In another embodiment, the semiconductor package 100 further includes a thermal interface material (TIM) 130 located between the upper surface 102 of the package structure 150 and the central portion 143 of the lid 140, where the TIM 130 includes at least one of graphite and a metal.

In another embodiment, the central portion 143 of the lid 140 is located over a first set of semiconductor dies 103 of the plurality of semiconductor dies 103 and is not located over a second set of semiconductor dies 103 of the plurality of semiconductor dies 103.

In another embodiment, the first set of semiconductor dies 103 includes logic dies 103a, and the second set of semiconductor dies 103 includes at least one of memory dies 103b and dummy dies 103c.

In another embodiment, the lid 140 includes open regions between adjacent connecting arms 145.

In another embodiment, each of the connecting arms 145 extending in an oblique vertically downward direction extend between corner regions of the sidewall portion 141 and corner regions of the central portion 143 of the lid 140.

In another embodiment, the central portion 143 of the lid 140 includes cutout regions in which the central portion 143 of the lid 140 does not cover the underlying package structure 150, and pairs of connecting arms 145 extend from the sidewall portion 141 to opposite sides of each of the cutout regions.

In another embodiment, a first group of connecting arms 145 extend parallel to one another between lateral side surfaces of the sidewall portion 141 and lateral side surfaces of the central portion 143 along a first horizontal direction hd1 and a second group of connecting arms 145 extend parallel to one another between lateral side surfaces of the sidewall portion 141 and lateral side surfaces of the central portion 143 along a second horizontal direction hd2 that is perpendicular to the first horizontal direction hd1.

In another embodiment, the central portion 143 of the lid 140 is located over semiconductor dies 103 in a central region of the package structure 150, and the central potion 143 of the lid 140 is not located over semiconductor dies 103 on the periphery of the package structure 150.

An additional embodiment is drawn to a lid 140 for a semiconductor package 100 including a sidewall portion 141, a central portion 143 located interior of the sidewall portion 141, and a plurality of connecting arms 145 extending between the sidewall portion 141 and the central portion 143 of the lid 140, where each of the connecting arms 145 includes a first end 147 connected to the sidewall portion 141 and a second end 149 connected to the central portion 143, and a line segment extending between the first end 147 and the second end 147 of each of the connecting arms 145 has an angle θ between −5° and −25° with respect to a horizontal plane.

In one embodiment, the plurality of connecting arms 145 are configured such that thermal expansion of the lid 140 causes the central portion 143 of the lid 140 to be displaced in a vertically downward direction.

In another embodiment, each of the connecting arms 145 includes a straight arm extending between the sidewall portion 141 and the central portion 143.

In another embodiment, each of the connecting arms 145 includes a curved arm extending between the sidewall portion 141 and the central portion 143.

In another embodiment, each of the connecting arms 145 includes a bent region.

An additional embodiment is drawn to a method of fabricating a semiconductor package 100 that includes mounting a package structure 150 including at least one semiconductor die 103 to a package substrate 120, and attaching a lid 140 to the package substate 120, where the lid 140 includes a sidewall portion 141 laterally surrounding the package structure 150, a central portion 143 in contact with an upper surface 102 of the package structure 150, and a plurality of connecting arms 145 extending in an oblique vertically downward direction between the sidewall portion 141 and the central portion 143 of the lid 140.

In an embodiment, the method further includes providing a thermal interface material (TIM) 130 over the upper surface 102 of the package structure 150, where the lid 140 is attached to the package substrate 120 such that the TIM 130 is located between the upper surface 102 of the package structure 150 and the central region 143 of the lid 140.

In another embodiment, each of the connecting arms 145 includes a first end 147 connected to the sidewall portion 141 and a second end 149 connected to the central portion 143, and a line segment extending between the first end 147 and the second end 147 of each of the connecting arms 145 has an angle θ between −5° and −25° with respect to a horizontal plane.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package, comprising:
a package substrate;
a package structure comprising at least one semiconductor die mounted to the package substrate; and
a lid, comprising:
a sidewall portion attached to the package substrate and laterally surrounding the package structure;
a central portion in contact with an upper surface of the package structure;
and a plurality of connecting arms extending between the sidewall portion and the central portion of the lid, wherein:
the central portion of the lid is vertically recessed from an upper portion of the sidewall portion to which the plurality of connecting arms are attached, and at least one of the plurality of connecting arms extends in an oblique vertically downward direction between the sidewall portion and the central portion of the lid.

2. The semiconductor package of claim 1, wherein a plurality of the connecting arms extend in an oblique vertically downward direction between the sidewall portion and the central portion of the lid, and each of the plurality of connecting arms extending in an oblique vertically downward direction comprises a first end connected to the sidewall portion and a second end connected to the central portion, and a line segment extending between the first end and the second end of each of the plurality of connecting arms extending in an oblique vertically downward direction has an angle between −5° and −25° with respect to a horizontal plane.

3. The semiconductor package of claim 1, wherein the package structure comprises a plurality of semiconductor dies surrounded by a molding portion, wherein the upper surface of the package structure is formed by upper surfaces of the plurality of semiconductor dies and the molding portion.

4. The semiconductor package of claim 3, wherein the package structure further comprises an interposer located between the plurality of semiconductor dies and the package substrate.

5. The semiconductor package of claim 3, further comprising a thermal interface material (TIM) located between the upper surface of the package structure and the central portion of the lid, wherein the TIM comprises at least one of graphite and a metal.

6. The semiconductor package of claim 3, wherein the central portion of the lid is located over a first set of semiconductor dies of the plurality of semiconductor dies and is not located over a second set of semiconductor dies of the plurality of semiconductor dies.

7. The semiconductor package of claim 6, wherein the first set of semiconductor dies comprises logic dies, and the second set of semiconductor dies comprises at least one of memory dies and dummy dies.

8. The semiconductor package of claim 1, wherein the lid comprises open regions between adjacent connecting arms.

9. The semiconductor package of claim 2, wherein each of the plurality of connecting arms extending in an oblique vertically downward direction extend between corner regions of the sidewall portion and corner regions of the central portion of the lid.

10. The semiconductor package of claim 1, wherein the central portion of the lid comprises cutout regions in which the central portion of the lid does not cover the underlying package structure, and pairs of connecting arms extend from the sidewall portion to opposite sides of each of the cutout regions.

11. The semiconductor package of claim 1, wherein a first group of connecting arms extend parallel to one another between lateral side surfaces of the sidewall portion and lateral side surfaces of the central portion along a first horizontal direction and a second group of connecting arms extend parallel to one another between lateral side surfaces of the sidewall portion and lateral side surfaces of the central portion along a second horizontal direction that is perpendicular to the first horizontal direction.

12. The semiconductor package of claim 11, wherein the central portion of the lid is located over semiconductor dies in a central region of the package structure, and the central portion of the lid is not located over semiconductor dies on a periphery of the package structure.

13. A lid for a semiconductor package, comprising:
a sidewall portion;
a central portion located interior of the sidewall portion; and
a plurality of connecting arms extending between the sidewall portion and the central portion of the lid, wherein each of the plurality of connecting arms comprises a first end connected to the sidewall portion and a second end connected to the central portion, and a line segment extending between the first end and the second end of each of the plurality of connecting arms has an angle between −5° and −25° with respect to a horizontal plane.

14. The lid of claim 13, wherein the plurality of connecting arms are configured such that thermal expansion of the lid causes the central portion of the lid to be displaced in a vertically downward direction.

15. The lid of claim 13, wherein each of the plurality of connecting arms comprises a straight arm extending between the sidewall portion and the central portion.

16. The lid of claim 14, wherein each of the plurality of connecting arms comprises a curved arm extending between the sidewall portion and the central portion.

17. The lid of claim 14, wherein each of the plurality of connecting arms comprises a bent region.

18. A method of fabricating a semiconductor package, comprising:
mounting a package structure comprising at least one semiconductor die to a package substrate; and
attaching a lid to the package substrate, wherein the lid comprises a sidewall portion laterally surrounding the package structure, a central portion in contact with an upper surface of the package structure, and a plurality of connecting arms extending in an oblique vertically downward direction between the sidewall portion and the central portion of the lid.

19. The method of claim 18, further comprising:
providing a thermal interface material (TIM) over the upper surface of the package structure, wherein the lid is attached to the package substrate such that the TIM is located between the upper surface of the package structure and a central region of the lid.

20. The method of claim 18, wherein each of the plurality of connecting arms comprises a first end connected to the sidewall portion and a second end connected to the central portion, and a line segment extending between the first end and the second end of each of the connecting arms has an angle between −5° and −25° with respect to a horizontal plane.
